(19) United States
(12) Patent Application Publication
(10) Pub. No.: US 2012/0039036 A1
(43) Pub. Date: Feb. 16, 2012

(54) THERMAL BUS BAR FOR A BLADE ENCLOSURE

(76) Inventors: Michael R. Krause, Boulder Creek, CA (US); Brandon Rubenstein, Loveland, CO (US); Roy Zeighami, Mckinney, TX (US); Fred B. Worley, San Jose, CA (US)

(21) Appl. No.: 13/259,019

(22) PCT Filed: Oct. 30, 2009
(86) PCT No.: PCT/US2009/062703

§ 371 Date: Sep. 22, 2011

(51) Int. Cl. H05K 7/20

(52) U.S. Cl. 361/679.47

(57) ABSTRACT

A cooling system for a blade enclosure is disclosed. The cooling system comprises a thermal bus bar (TBB) 1220 positioned in the middle of the blade enclosure. The TBB 122 has a front face and a back face. When blades are inserted into the blade enclosure, a heat transfer plate 584 on the blade makes thermal contact with either the front or back face of the TBB 122. The TBB 122 is cooled, thereby cooling the blades.

### BACKGROUND

Many datacenters are now populated with computer blades mounted in blade enclosures. A computer blade is defined as a device that accesses power and connections to other blades and devices through a shared infrastructure or enclosure. The computer blade may be rack mounted into the enclosure. A computer blade may also be defined as a device that provides power and connectivity to other blades and devices through the shared infrastructure or enclosure. A computer blade can fulfill a number of different functions. There are blade servers, Input/Output (I/O) blades, memory blades, power supply blades, I/O interconnect blades, and the like. As the computer blades have increased in power density, cooling the blades has become a challenge.

Blades are typically cooled by drawing ambient air through the blade enclosure to remove the heat generated by the components mounted on the blades. This solution requires the ambient air to be conditioned to a specific temperature and humidity. Without conditioning, the components may be subject to insufficient cooling, humidity damage, or contamination. Conditioning the air can use a significant portion of the energy required by the datacenter.

### BRIEF DESCRIPTION OF THE DRAWINGS

FIG. 1A is an isometric view of a blade enclosure 100 in an example embodiment of the invention.

FIG. 1B is a cut-away side view of blade enclosure 100 in an example embodiment of the invention.

FIG. 2A is an isometric view of cooling assembly 106 with the top cover of cooling base 120 removed, in an example embodiment of the invention.

FIG. 2B is a top view of cooling assembly 106 with the top cover of cooling base 120 removed, in an example embodiment of the invention.

FIG. 3 is a diagram of the cooling pathways in cooling assembly 106 in one example embodiment of the invention.

FIG. 4A is a diagram of the cooling pathways in cooling assembly 106 in another example embodiment of the invention.

FIG. 4B is a diagram showing the temperature gradient of the TBB from FIG. 4A in an example embodiment of the invention.

FIG. 5 is an isometric view of a blade in an example embodiment of the invention.

### DETAILED DESCRIPTION

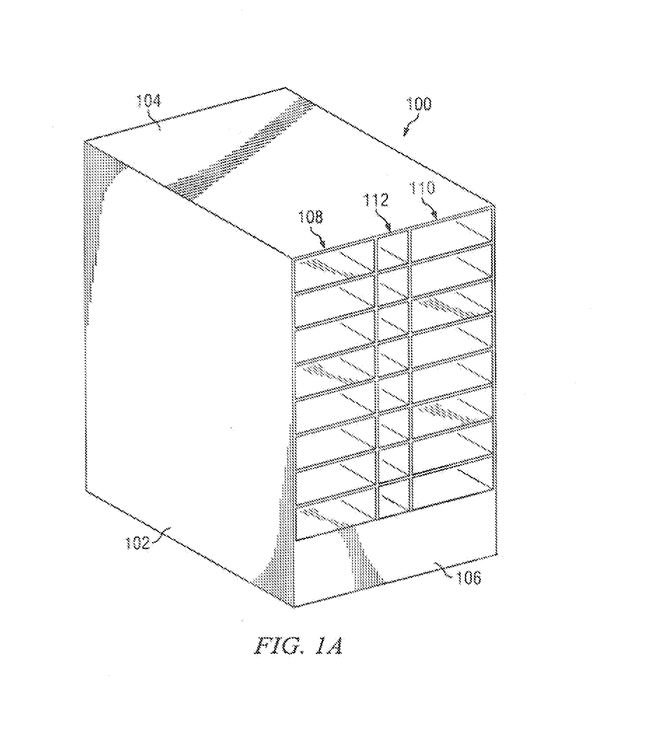

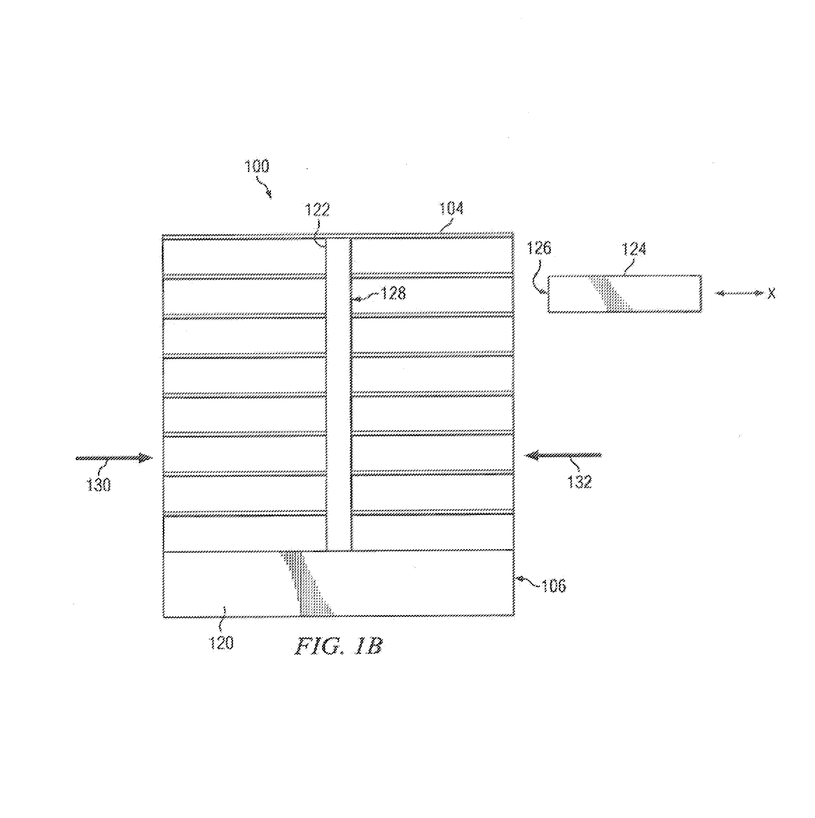

FIGS. 1-5, and the following description depict specific examples to teach those skilled in the art how to make and use the best mode of the invention. For the purpose of teaching inventive principles, some conventional aspects have been simplified or omitted. Those skilled in the art will appreciate variations from these examples that fall within the scope of the invention. Those skilled in the art will appreciate that the features described below can be combined in various ways to form multiple variations of the invention. As a result, the invention is not limited to the specific examples described below, but only by the claims and their equivalents.

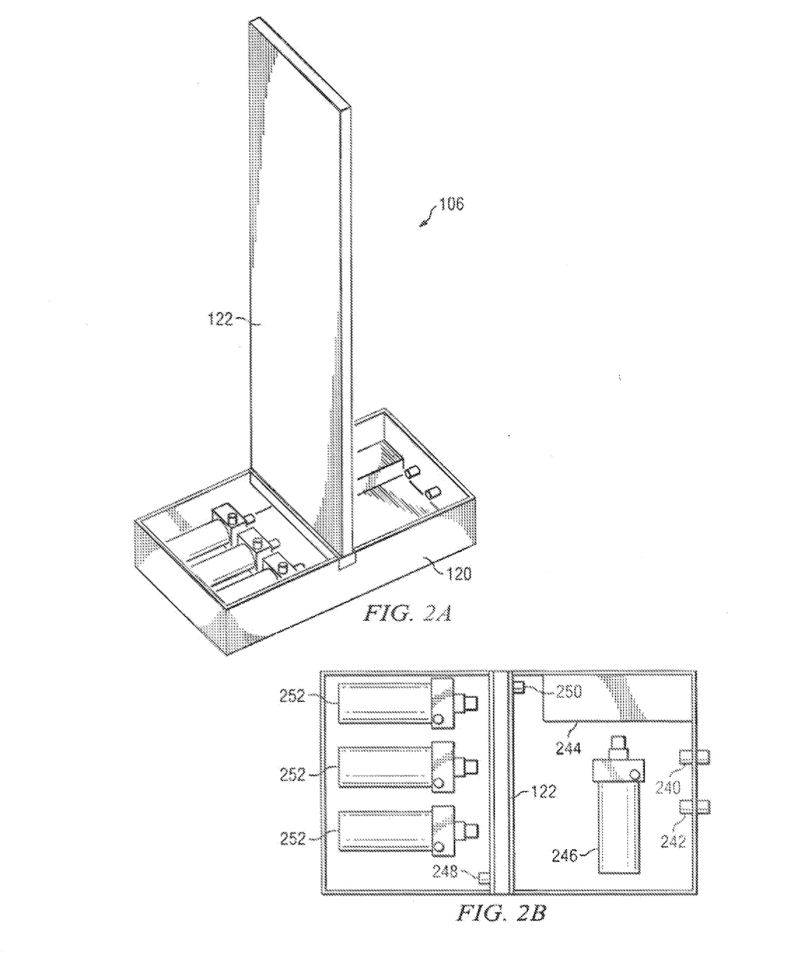

FIG. 1A is an isometric view of a blade enclosure 100 in an example embodiment of the invention. Blade enclosure 100 comprises left and right side panels 102, top panel 104, and cooling assembly 106. The front face of blade enclosure 100 has a first column of smaller openings or slots 112 in the center of the front face and a left and right column (108 and 110) of larger openings or slots on either side of the column of smaller openings or slots. Cooling assembly 106 is located in the bottom of blade enclosure 100 and has a thermal bus bar (TBB) extending up through the middle of blade enclosure (see FIG. 2). In one example embodiment of the invention, the column of smaller slots 112 are configured to receive power supply blades and the two columns of larger slots are configured to receive a plurality of different types of computer blades.

FIG. 1A shows the slots with a horizontal orientation, but in other example embodiments the slots may be oriented vertically. FIG. 1A shows the center column of smaller slots 112 configured to receive power supply blades, but in other example embodiments the power supply slots may be the same size as the blade slots, or may be distributed in the enclosure as a number of rows. In one example embodiment of the invention, blade enclosure is symmetrical and the back face of the blade enclosure is a mirror image of the front face (i.e. three columns of slots). In other example embodiments of the invention the slot configuration on the back face may be different than the slot configuration on the front face.

FIG. 1B is a cut-away side view of blade enclosure 100 in an example embodiment of the invention. Blade enclosure 100 comprises top panel 104, a plurality of slots on the front face 132, a plurality of slots on the back face 130, and cooling assembly 106. Cooling assembly 106 comprises cooling base 120 and thermal bus bar (TBB) 122. Cooling base is located in the bottom section of blade enclosure 100. TBB 122 attaches to the top side of cooling base 120 and extends up through the middle of blade enclosure 100.

TBB 122 provides cooling to blades inserted into the slots on the front and back face of blade enclosure 100. Blade 124 is shown positioned to be installed/inserted along axis X into one of the plurality of slots on the front side 132 of blade enclosure 100. Once inserted, the back end 126 of blade 124 will be in thermal contact with surface 128 on the front side of the TBB 122. Other blades (not shown) may be inserted into the slots on the back face of blade enclosure 100. Once inserted, the back end of the blade would make thermal contact with the back face of TBB 122.

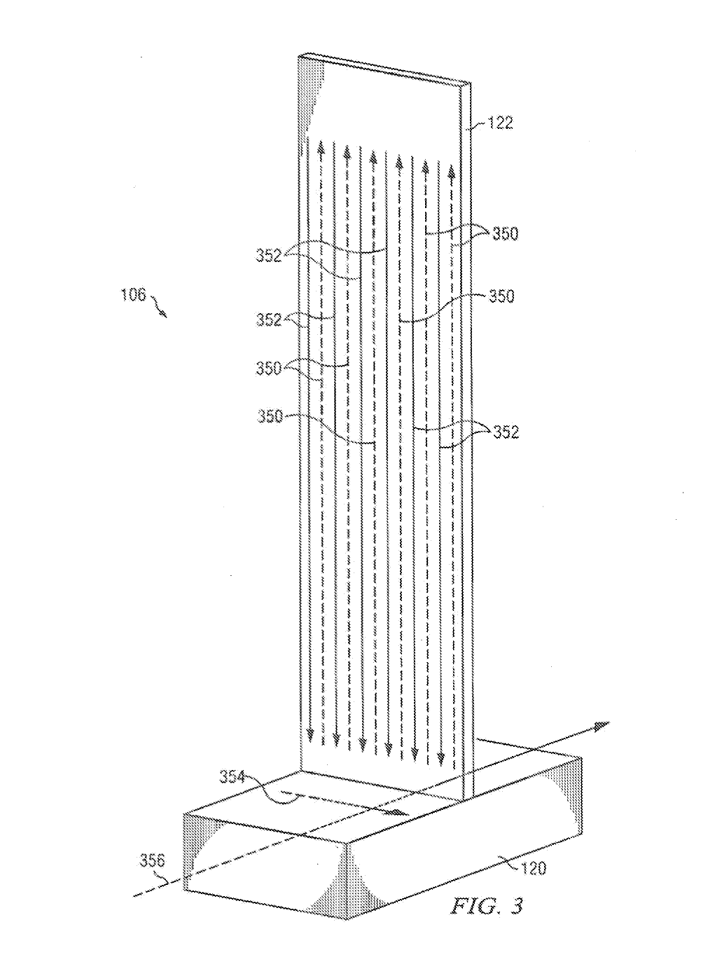

FIG. 2A is an isometric view of cooling assembly 106 with the top cover of cooling base 120 removed, in an example embodiment of the invention. TBB 122 is a generally rectangular part positioned perpendicular with, and positioned in the middle of, the top of cooling base 120. TBB 122 is filled with a number of fluid channels that allow cooling fluid to be pumped from cooling base 120, up and around the TBB 122, and then back into cooling base 120 (see FIG. 3). Cooling base 120 is generally a rectangular enclosure that holds the piping, pumps and heat exchanger for TBB 122.

FIG. 2B is a top view of cooling assembly 106 with the top cover of cooling base 120 removed, in an example embodiment of the invention. Cooling assembly comprises TBB 122, a plurality of TBB pumps 252, a heat exchanger 244, and a heat exchanger pump 246. A plurality of pipes couple the different elements in cooling assembly together, but are not shown for clarity. A first fluid system is fully contained within cooling assembly 106. The first fluid cooling system runs from a TBB fluid inlet 248, up through the fluid channels in the TBB 122, out of the TBB fluid outlet 250, through the heat exchange 244, to pumps 252, and then back to the TBB fluid inlet 248. The first fluid system is configured to cool the TBB 122, thereby cooling blades in thermal contact with the TBB 122. The first fluid cooling system dumps the heat from the TBB into heat exchanger 244. In some example embodiments of the invention, the plurality of TBB pumps 252 may be redundantly configured to provide circulation through the first fluid system even after one or more of the pumps have failed.

The second fluid cooling system runs from external cooling system inlet 242 to heat exchanger pump 246, through heat exchanger 244, and then to external cooling system exit 240. In operation, the external cooling system inlet 242 and external cooling system exit 240 will be coupled to an external fluid cooling system that provides cooled fluid to the external cooling system inlet 242 and removes the heated fluid from the external cooling system exit 240. In some example embodiments of the invention, heat exchanger pump 246 may be located external to blade enclosure 100. In some example embodiments of the invention, the first and second cooling systems may be combined into only one fluid cooling system.

FIG. 3 is a diagram of the cooling pathways in cooling assembly 106 in one example embodiment of the invention. FIG. 3 shows a plurality of input cooling channels 350 that go up the TBB 122, interleaved with a plurality of return cooling channels 352 that go back down TBB 122. In operation, cooled fluid is pumped up the cooling channels 350 and back down the return cooling channels 352. As the cooled fluid travels around TBB 122, heat is removed from any blades in thermal contact with TBB 122. The heated fluid exits the TBB and flows through the heat exchanger (represented by crossed arrows 354 and 356). Heat from the blades is transferred to an externally cooled fluid in the heat exchanger, and then the cooled fluid is returned to the TBB 122. Fluid cooled externally flows into cooling assembly 106 (represented by arrow 356), through heat exchanger, and then exits cooling assembly 106. As the externally cooled fluid passes through the heat exchanger, the heat from the blades is transferred to the externally cooled fluid, and then flows out of cooling assembly 106.

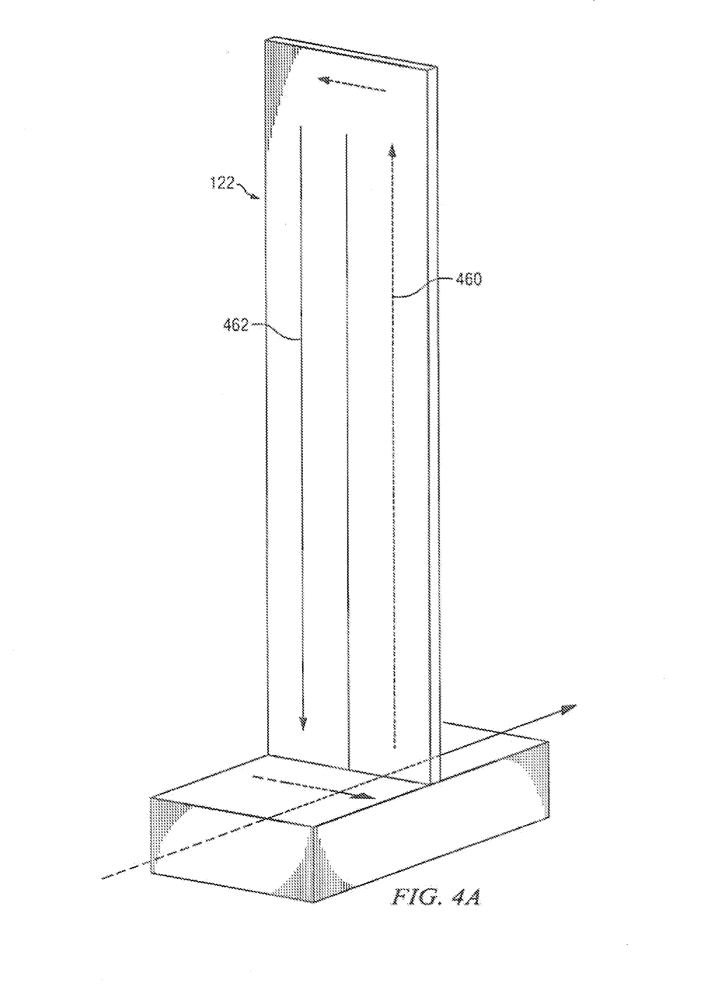

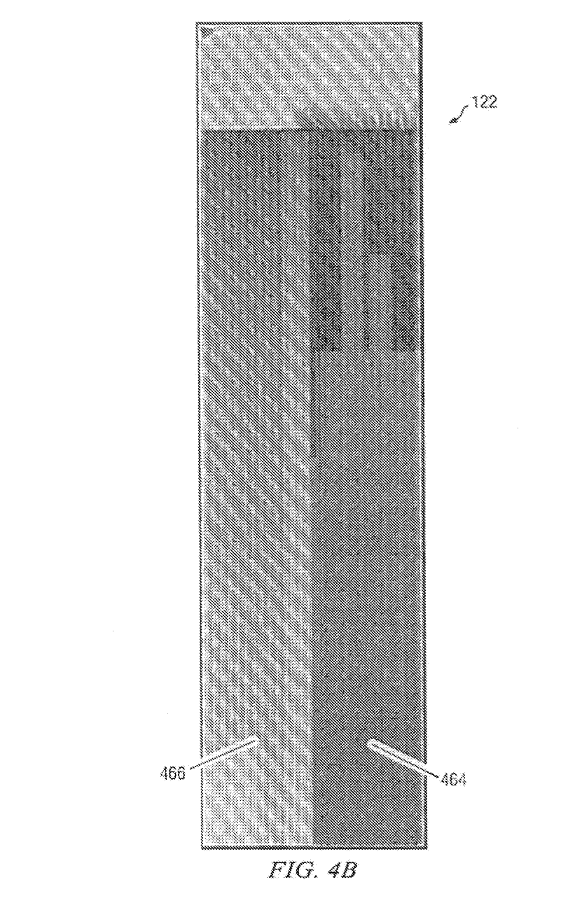

In one example embodiment of the invention, the input cooling channels 350 are interleaved with the return cooling channels 352. By interleaving the input cooling channels with the return cooling channels, the temperature gradient across TBB 122 remains fairly constant. FIG. 4A is a diagram of the cooling pathways in cooling assembly 106 in another example embodiment of the invention. FIG. 4A shows all the input cooling channels 460 going up one side of TBB 122 and all the return cooling channels 462 going down the other side of TBB 122. This will produce an uneven temperature gradient across TBB 122.

FIG. 4B is a diagram showing the temperature gradient of the TBB from FIG. 4A in an example embodiment of the invention. On the bottom right side (area 464) where the cool fluid first enters the TBB 122 the temperature gradient is the largest. This area 464 would provide the highest level of cooling in the blade enclosure. As the cooling fluid travels up the right side of TBB 122, and then down the left side of TBB 122, the fluid is warmed up as it removes heat from any blades in thermal contact with TBB 122. Once the cooling fluid reaches the lower left side of TBB 122 (area 466) the fluid is the warmest and the thermal gradient is the smallest. This area 466 on the TBB 122 would provide the least amount of cooling for the blade enclosure.

In other example embodiments, the cooling channels in TBB 122 may be arranged in other configurations, for example having channels that flow across the TBB (instead of up and down). These channels may be configured to provide uniform cooling across the TBB, or may be configured to create zones of higher and lower cooling areas across TBB 122.

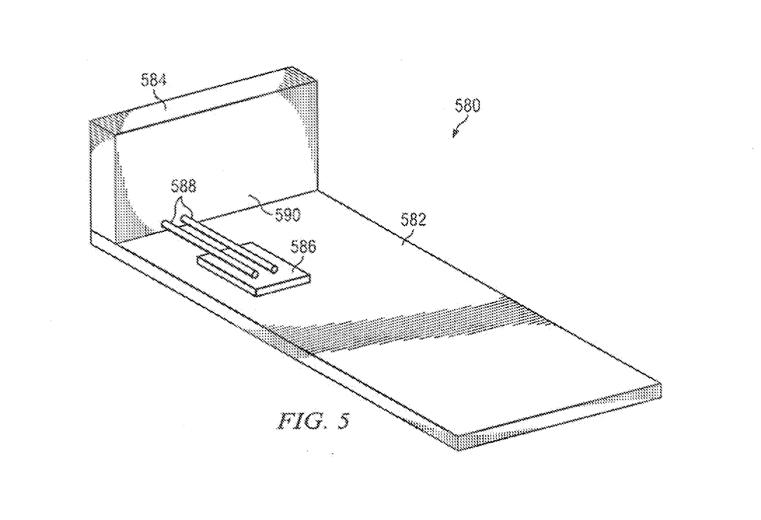

FIG. 5 is an isometric view of a blade 580 in an example embodiment of the invention. Blade 580 comprises printed circuit (PC) board 582, heat transfer plate 584, component 586, and a plurality of heat pipes 588. Heat transfer plate 584 is a generally rectangular plate mounted at the back end of PC board 582. Heat transfer plate has a front side 590 and a back side (not shown). Heat transfer plate is mounted perpendicular with the top surface of PC board 582. Component 586 is mounted to the top surface of PC board 582. The hot ends of the plurality of heat pipes 588 are positioned on top of component 586. The cool ends of the plurality of heat pipes 588 are coupled to heat transfer plate 584. In some example embodiments of the invention, electrical signals and power signals from blade 580 may connect to blade enclosure 100 through the back end of blade 580, but these connections are not show for clarity.

When blade 580 is inserted into one of the plurality of blade slots in the front face of blade enclosure 100, the back side of the heat transfer plate 584 will make thermal contact with the front face 128 of TBB 122. During operation, heat generated by component 586 will be transferred into the hot side of the plurality of heat pipes 588. The heat pipes will transfer the heat into heat transfer plate 584. The heat from the heat transfer plate will be transferred into the TBB. The cooled fluid circulating inside the TBB will remove the heat from the TBB thereby cooling blade 580. In other example embodiments of the invention, heat from component 586 may be transferred to heat transfer plate 584 using other methods instead of, or in addition too, the plurality of heat pipes. Blade 580 may comprise other element that have been removed for clarity, for example the blade sides, the blade end cover, locking devices, additional components, and the like.

1. A blade enclosure, comprising:
an enclosure structure having a first side and a second side opposite the first side, a front side and a back side opposite the front side, the front side and the back side both having a plurality of openings configured to accept a plurality of blades;
a cooling assembly mounted in the enclosure structure, the cooling assembly comprising:
a thermal bus bar (TBB) having a generally rectangular shape wherein the TBB is located inside the blade enclosure, parallel with the front side of the enclosure structure, the TBB is positioned between the front side and the back side of the enclosure structure;
a plurality of cooling fluid channels running through the TBB;
a cooling fluid inlet coupled to at least one of the plurality of cooling fluid channels and a cooling fluid outlet coupled to at least one of the cooling fluid channels wherein a fluid cooling path is formed between the cooling fluid inlet, the cooling fluid channels and the cooling fluid outlet;
a front face of the TBB open to the plurality of slots in the front side of the enclosure structure and configured to make thermal contact with a back end of a blade when the blade is installed into one of the plurality of slots in the front side of the enclosure structure;
a back face of the TBB open to the plurality of slots in the back side of the enclosure structure and configured to make thermal contact with a back end of a blade when the blade is installed into one of the plurality of slots in the back side of the enclosure structure.

2. The blade enclosure of claim 1, wherein the cooling assembly further comprises:
a cooling base forming a generally rectangular enclosure, the cooling base located in a bottom section of enclosure structure, the TBB mounted on top of the cooling base;
at least one TBB pump located inside the cooling base;
a heat exchanger located inside the cooling base;
a first piping system coupled to the at least one TBB pump, the heat exchanger, the cooling fluid inlet, and the cooling system outlet, wherein the first piping system forms a re-circulating fluid pathway between the TBB, the heat exchanger and the at least one TBB pump.

3. The blade enclosure of claim 2, wherein the cooling assembly further comprises:
a plurality of TBB pumps wherein the first piping system is configured to redundantly couple the plurality of TBB pumps with the re-circulating fluid pathway.

4. The blade enclosure of claim 2, wherein the cooling assembly further comprises:
an external fluid inlet and an external fluid outlet;
a second piping system wherein the second piping system couples the external fluid inlet and the external fluid outlet with the heat exchanger;
an external fluid cooling system coupled to the external fluid inlet and the external fluid outlet and configured to provide cooled fluid to the external fluid inlet and remove heated fluid from the external fluid outlet.

5. The blade enclosure of claim 1, wherein the cooling fluid inlet and the cooling fluid outlet are coupled to an external cooling fluid supply system configured to provide cool fluid to the cooling system inlet and remove heated fluid from the cooling system outlet.

6. The blade enclosure of claim 1, wherein the plurality of cooling fluid channels comprise a first set of input channels and a second set of output channels and the first set of input channels are interspaced with the second set of output channels.

7. The blade enclosure of claim 1, wherein the plurality of cooling fluid channels are configured to provide a highest level of cooling for a first set of the plurality of slots and a lowest level of cooling for a second set of the plurality of slots.

8. The blade enclosure of claim 1, further comprising:
at least one blade inserted into one of the plurality of slots on the front side of the enclosure structure wherein a back side of the blade makes thermal contact with the front face of the TBB.

9. The blade enclosure of claim 8, wherein the computer blade is selected from one of the following types of computer blades: a blade server, a memory blade, an input/output (I/O) blade, a blade fabric, and a power supply blade.

10. A method for cooling a blade enclosure, comprising:
providing a plurality of blade mounting slots in a front side of the blade enclosure, wherein when a blade is installed into one of the plurality of blade mounting slots in the front side of the blade enclosure, a heat transfer plate on a back end of the blade makes thermal contact with a front face of a thermal bus bar (TBB) positioned in a middle of the blade;
providing a plurality of blade mounting slots in a back side of the blade enclosure, wherein when a blade is installed into one of the plurality of blade mounting slots in the back side of the blade enclosure, a heat transfer plate on a back end of the blade makes thermal contact with a back face of the TBB;
cooling the TBB.

11. The method for cooling a blade enclosure of claim 10, further comprising:
installing a computer blade into the blade enclosure thereby thermally coupling a heat transfer plate on the computer blade to the TBB in the blade enclosure.

12. The method for cooling a blade enclosure of claim 11, wherein the computer blade is selected from one of the following types of computer blades: a blade server, a memory blade, an input/output (I/O) blade, a blade fabric, and a power supply blade.

13. The method for cooling a blade enclosure of claims 10, wherein the TBB is cooled by a re-circulating fluid cooling system contained in the blade enclosure.

14. The method for cooling a blade enclosure of claims 10, wherein the TBB is cooled evenly across the TBB.
